(19) United States
(12) Patent Application Publication
(10) Pub. No.: US 2025/0081808 A1
(43) Pub. Date: Mar. 6, 2025

(54) DISPLAY DEVICE

(71) Applicant: Japan Display Inc., Tokyo (JP)

(72) Inventor: Kaichi FUKUDA, Tokyo (JP)

(73) Assignee: Japan Display Inc., Tokyo (JP)

(21) Appl. No.: 18/791,432

(22) Filed: Aug. 1, 2024

(30) Foreign Application Priority Data
Sep. 6, 2023 (JP) 2023-144496

(51) Int. Cl. H10K 59/80; H10K 59/122

(52) U.S. Cl. CPC H10K 59/8722; H10K 59/122; H10K 59/80517; H10K 59/80518

(57) ABSTRACT

According to one embodiment, a display device includes a lower electrode, a rib which has a pixel aperture overlapping the lower electrode and covers an end portion of the lower electrode, a partition which includes a bottom portion the rib, a lower portion on the bottom portion, and an upper portion on the lower portion and protruding from a side surface of the lower portion, an organic layer which is in contact with the lower electrode through the pixel aperture, an upper electrode which covers the organic layer and is in contact with at least one of the bottom portion and the lower portion, and a transparent conductive oxide layer provided between the rib and the bottom portion.

### CROSS-REFERENCE TO RELATED APPLICATIONS

This application is based upon and claims the benefit of priority from Japanese Patent Application No. 2023-144496, filed Sep. 6, 2023, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. In this type of display devices, a technique which can improve the yield is required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is a schematic cross-sectional view of the display device along the III-III line of FIG. 2.

FIG. 4 is a diagram showing an example of a layer structure which could be applied to an organic layer.

FIG. 5 is a schematic cross-sectional view in which a partition and its vicinity are enlarged according to the first embodiment.

FIG. 6 is a schematic cross-sectional view in which a bottom portion and the vicinity of an end portion of a conductive oxide layer are enlarged according to the first embodiment.

FIG. 7A is a schematic cross-sectional view showing the manufacturing process of the display device according to the first embodiment.

FIG. 7B is a schematic cross-sectional view showing a manufacturing process following FIG. 7A.

FIG. 7C is a schematic cross-sectional view showing a manufacturing process following FIG. 7B.

FIG. 7D is a schematic cross-sectional view showing a manufacturing process following FIG. 7C.

FIG. 7E is a schematic cross-sectional view showing a manufacturing process following FIG. 7D.

FIG. 7F is a schematic cross-sectional view showing a manufacturing process following FIG. 7E.

FIG. 7G is a schematic cross-sectional view showing a manufacturing process following FIG. 7F.

FIG. 7H is a schematic cross-sectional view showing a manufacturing process following FIG. 7G.

FIG. 7I is a schematic cross-sectional view showing a manufacturing process following FIG. 7H.

FIG. 7J is a schematic cross-sectional view showing a manufacturing process following FIG. 7I.

FIG. 7K is a schematic cross-sectional view showing a manufacturing process following FIG. 7J.

FIG. 7L is a schematic cross-sectional view showing a manufacturing process following FIG. 7K.

FIG. 7M is a schematic cross-sectional view showing a manufacturing process following FIG. 7L.

FIG. 8A is a schematic cross-sectional view showing a manufacturing process for forming display elements.

FIG. 8B is a schematic cross-sectional view showing a manufacturing process following FIG. 8A.

FIG. 8C is a schematic cross-sectional view showing a manufacturing process following FIG. 8B.

FIG. 8D is a schematic cross-sectional view showing a manufacturing process following FIG. 8C.

FIG. 9 is a schematic cross-sectional view of a display device according to a second embodiment.

FIG. 10 is a schematic plan view of a rib, lower electrodes and conductive layers according to the second embodiment.

FIG. 11 is a schematic cross-sectional view in which the partition shown in FIG. 9 and its vicinity are enlarged.

FIG. 12A is a schematic cross-sectional view showing the manufacturing process of the display device according to the second embodiment.

FIG. 12B is a schematic cross-sectional view showing a manufacturing process following FIG. 12A.

FIG. 12C is a schematic cross-sectional view showing a manufacturing process following FIG. 12B.

FIG. 12D is a schematic cross-sectional view showing a manufacturing process following FIG. 12C.

FIG. 12E is a schematic cross-sectional view showing a manufacturing process following FIG. 12D.

FIG. 12F is a schematic cross-sectional view showing a manufacturing process following FIG. 12E.

FIG. 12G is a schematic cross-sectional view showing a manufacturing process following FIG. 12F.

FIG. 12H is a schematic cross-sectional view showing a manufacturing process following FIG. 12G.

FIG. 12I is a schematic cross-sectional view showing a manufacturing process following FIG. 12H.

FIG. 12J is a schematic cross-sectional view showing a manufacturing process following FIG. 12I.

FIG. 12K is a schematic cross-sectional view showing a manufacturing process following FIG. 12J.

FIG. 12L is a schematic cross-sectional view showing a manufacturing process following FIG. 12K.

FIG. 12M is a schematic cross-sectional view showing a manufacturing process following FIG. 12L.

### DETAILED DESCRIPTION

In general, according to one embodiment, a display device comprises a lower electrode, a rib which has a pixel aperture overlapping the lower electrode and covers an end portion of the lower electrode, a partition which includes a bottom portion provided on the rib, a lower portion provided on the bottom portion, and an upper portion provided on the lower portion and protruding from a side surface of the lower portion, an organic layer which is in contact with the lower electrode through the pixel aperture and emits light based on application of voltage, an upper electrode which covers the organic layer and is in contact with at least one of the bottom portion and the lower portion, and a transparent conductive oxide layer provided between the rib and the bottom portion.

According to another embodiment, a display device comprises a lower electrode, a rib which has a pixel aperture overlapping the lower electrode and covers an end portion of the lower electrode, a partition which includes a bottom portion provided on the rib, a lower portion provided on the bottom portion, and an upper portion provided on the lower portion and protruding from a side surface of the lower portion, an organic layer which is in contact with the lower electrode through the pixel aperture and emits light based on application of voltage, an upper electrode which covers the organic layer and is in contact with at least one of the bottom portion and the lower portion, and a transparent conductive oxide layer which is provided between the lower electrode and the rib and has an aperture overlapping the pixel aperture.

According to one embodiment, a manufacturing method of a display device includes forming a lower electrode, forming a rib which has a pixel aperture overlapping the lower electrode, forming a transparent conductive oxide layer which covers the lower electrode and the rib, forming, on the conductive oxide layer, a partition including a bottom portion located above the rib, a lower portion provided on the bottom portion, and an upper portion provided on the lower portion and protruding from a side surface of the lower portion, forming an organic layer which is in contact with the lower electrode through the pixel aperture and emits light based on application of voltage by removing a portion of the conductive oxide layer exposed from the bottom portion after forming the partition, and forming an upper electrode which covers the organic layer and is in contact with at least one of the bottom portion and the lower portion.

According to another embodiment, a manufacturing method of a display device includes forming a lower electrode, forming a transparent conductive oxide layer which covers the lower electrode, forming a rib which covers the conductive oxide layer and has a pixel aperture overlapping the lower electrode, forming a partition including a bottom portion located above the rib, a lower portion provided on the bottom portion, and an upper portion provided on the lower portion and protruding from a side surface of the lower portion, forming an organic layer which is in contact with the lower electrode through the pixel aperture and emits light based on application of voltage by removing a portion of the conductive oxide layer exposed from the rib through the pixel aperture after forming the partition, and forming an upper electrode which covers the organic layer and is in contact with at least one of the bottom portion and the lower portion.

Each embodiment can improve the yield of a display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

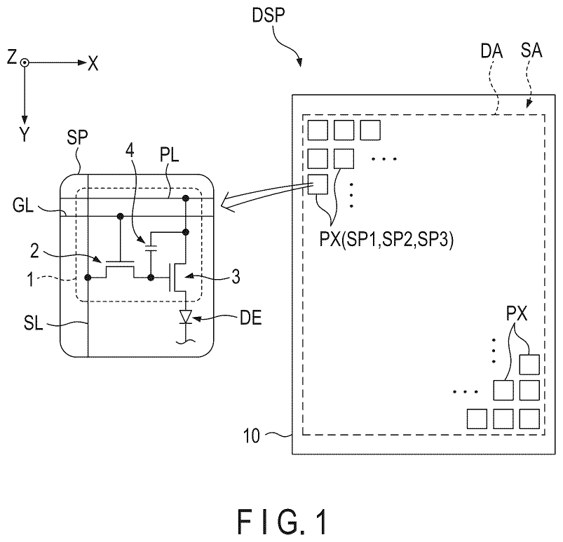

FIG. 1 is a diagram showing a configuration example of a display device DSP according to a first embodiment. The display device DSP comprises an insulating substrate 10. The substrate 10 has a display area DA which displays an image, and a surrounding area SA around the display area DA. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply a scanning signal to the pixel circuit 1 of each subpixel SP, a plurality of signal lines SL which supply a video signal to the pixel circuit 1 of each subpixel SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. One of the source electrode and drain electrode of the pixel switch 2 is connected to the signal line SL. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

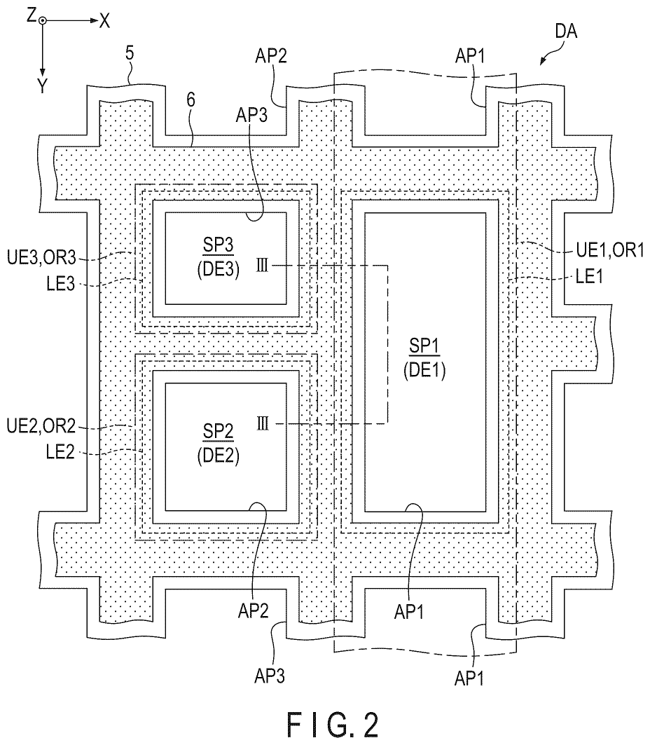

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib 5 is provided in the display area DA. The rib 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 surrounds each of these display elements DE1, DE2 and DE3.

A conductive partition 6 is provided on the rib 5. The partition 6 overlaps the rib 5 as a whole and has the same planar shape as the rib 5. In other words, the partition 6 has an aperture in each of subpixels SP1, SP2 and SP3. From another viewpoint, each of the rib 5 and the partition 6 has a grating shape as seen in plan view and surrounds each of subpixels SP1, SP2 and SP3. The partition 6 functions as lines which apply common voltage to the upper electrodes UE1, UE2 and UE3.

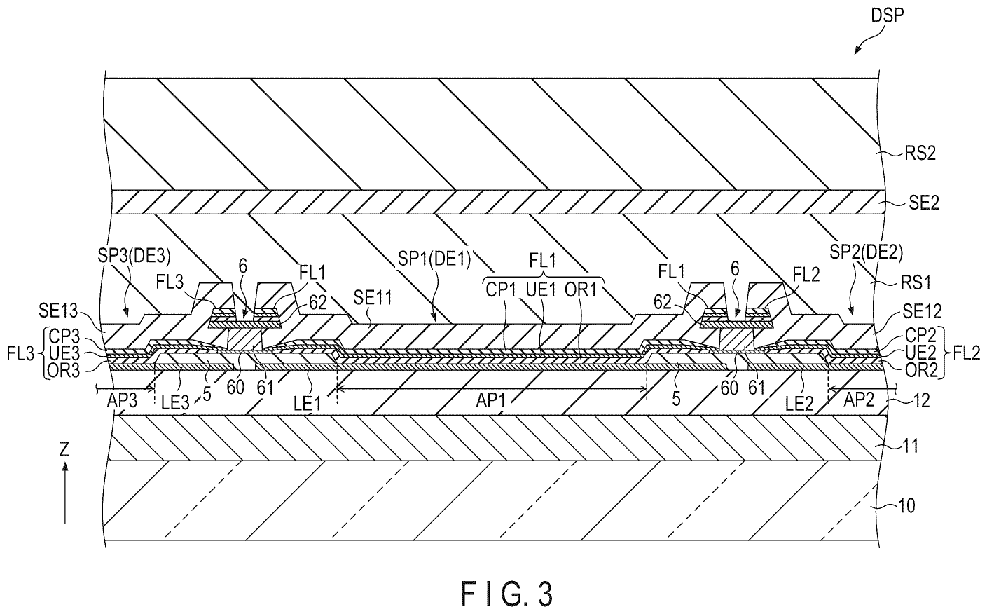

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuits 1, scanning lines GL, signal lines SL and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive bottom portion 60 provided above the rib 5, a conductive lower portion 61 provided on the bottom portion 60, and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape. In the example of FIG. 3, the both end portions of the bottom portion 60 also protrude from the side surfaces of the lower portion 61.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with at least one of the bottom portion 60 and the lower portion 61 of the partition 6.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located around the partition 6 (in other words, the portion which constitutes the display element DE1). Similarly, the stacked film FL2 is partly located on the upper portion 62. This portion is spaced apart from, of the stacked film FL2, the portion located around the partition 6 (in other words, the portion which constitutes the display element DE2). Further, the stacked film FL3 is partly located on the upper portion 62. This portion is spaced apart from, of the stacked film FL3, the portion located around the partition 6 (in other words, the portion which constitutes the display element DE3).

Sealing layers SE11, SE12 and SE13 are provided in subpixels SP1, SP2 and SP3, respectively. The sealing layer SE11 continuously covers the cap layer CP1 and the partition 6 around subpixel SP1. The sealing layer SE12 continuously covers the cap layer CP2 and the partition 6 around subpixel SP2. The sealing layer SE13 continuously covers the cap layer CP3 and the partition 6 around subpixel SP3.

In the example of FIG. 3, the stacked film FL1 and sealing layer SE11 located on the partition 6 between subpixels SP1 and SP2 are spaced apart from the stacked film FL2 and sealing layer SE12 located on this partition 6. The stacked film FL1 and sealing layer SE11 located on the partition 6 between subpixels SP1 and SP3 are spaced apart from the stacked film FL3 and sealing layer SE13 located on this partition 6.

The sealing layers SE11, SE12 and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib 5 and the sealing layers SE11, SE12, SE13 and SE2 is formed of an inorganic insulating material such as silicon nitride (SiNx), silicon oxide (Siox), silicon oxynitride (SiON) or aluminum oxide (Al₂O₃). Each of the resin layers RS1 and RS2 is formed of, for example, a resinous material (organic insulating material) such as epoxy resin or acrylic resin.

As explained in detail later, each of the lower electrodes LE1, LE2 an LE3 includes a reflective layer formed of a metal material. Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

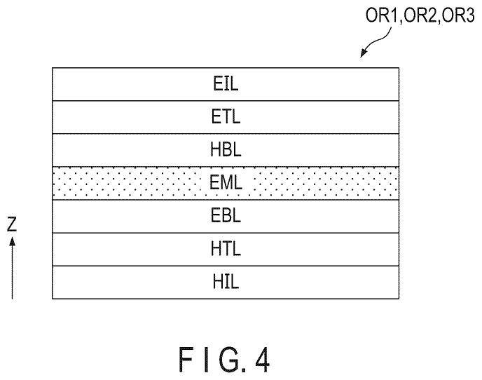

FIG. 4 is a diagram showing an example of a layer structure which could be applied to the organic layers OR1, OR2 and OR3. Each of the organic layers OR1, OR2 and OR3 consists of a plurality of thin films including a light emitting layer EML. This embodiment assumes a case where each of the organic layers OR1, OR2 and OR3 comprises a structure in which a hole injection layer HIL, a hole transport layer HTL, an electron blocking layer EBL, a light emitting layer EML, a hole blocking layer HBL, an electron transport layer ETL and an electron injection layer EIL are stacked in order in a Z-direction. It should be noted that each of the organic layers OR1, OR2 and OR3 may comprise another structure such as a tandem structure including a plurality of light emitting layers EML.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE1, SE2 and SE3. It should be noted that at least one of the cap layers CP1, CP2 and CP3 may be omitted.

Common voltage is applied to the partition 6. This common electrode is applied to the upper electrodes UE1, UE2 and UE3 which are in contact with at least one of the bottom portion 60 and the lower portion 61. Pixel voltage is applied to the lower electrodes LE1, LE2 and LE3 through the pixel circuits 1 of subpixels SP1, SP2 and SP3, respectively, based on the video signals of the signal lines SL.

The organic layers OR1, OR2 and OR3 emit light based on the application of voltage. Specifically, when a potential difference is formed between the lower electrode LE1 and the upper electrode UE1, the light emitting layer EML of the organic layer OR1 emits light in a blue wavelength range. When a potential difference is formed between the lower electrode LE2 and the upper electrode UE2, the light emitting layer EML of the organic layer OR2 emits light in a green wavelength range. When a potential difference is formed between the lower electrode LE3 and the upper electrode UE3, the light emitting layer EML of the organic layer OR3 emits light in a red wavelength range.

As another example, the light emitting layers EML of the organic layers OR1, OR2 and OR3 may emit light exhibiting the same color (for example, white). In this case, the display device DSP may comprise color filters which convert the light emitted from the light emitting layers EML into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers EML.

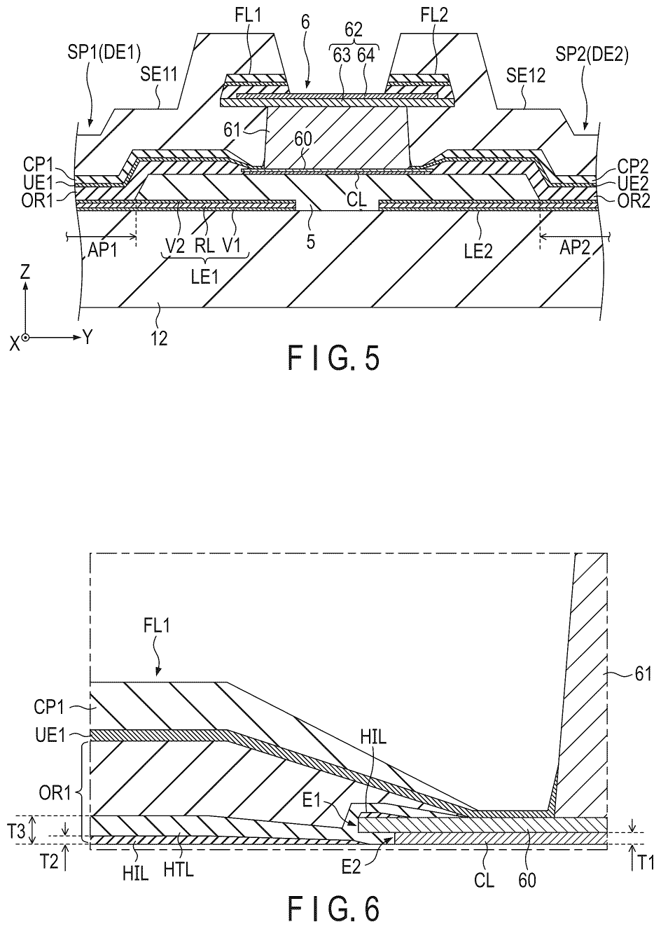

FIG. 5 is a schematic cross-sectional view in which the partition 6 and its vicinity are enlarged. In this figure, the substrate 10, the circuit layer 11, the resin layers RS1 and RS2 and the sealing layer SE2 are omitted.

In the example of FIG. 5, the lower electrode LE1 includes a reflective layer RL, a first coating layer V1 which covers the lower surface of the reflective layer RL, and a second coating layer V2 which covers the upper surface of the reflective layer RL. In the pixel aperture AP1, the organic layer OR1 is in contact with the second coating layer V2.

The reflective layer RL is formed of, for example, a metal material excellent in light reflectivity, such as silver. Each of the coating layers V1 and V2 is formed of, for example, a transparent conductive oxide such as indium tin oxide (ITO), indium zinc oxide (IZO) or indium gallium zinc oxide (IGZO). The configurations of the lower electrodes LE2 and LE3 are similar to the configuration of the lower electrode LE1. For example, the end portions of the lower electrodes LE1, LE2 and LE3 overlap the lower portion 61 in the Z-direction.

In the example of FIG. 5, the upper portion 62 of the partition 6 includes a first top layer 63 provided on the lower portion 61, and a second top layer 64 which covers the first top layer 63. The both end portions of each of the first top layer 63 and the second top layer 64 protrude from the side surfaces of the lower portion 61. The both end portions of the first top layer 63 are partly exposed from the second top layer 64.

The bottom portion 60 is formed of a conductive metal material. For this metal material, for example, titanium (Ti), titanium nitride (TiN), molybdenum (Mo), a molybdenum-tungsten alloy (MoW) or a molybdenum-niobium alloy (MoNb) can be used. The thickness of the bottom portion 60 is, for example, 10 to 50 nm.

The lower portion 61 is formed of, for example, a conductive metal material which is different from the bottom portion 60. For this metal material, for example, aluminum (Al), an aluminum-neodymium alloy (AlNd), an aluminum-yttrium alloy (AlY) or an aluminum-silicon alloy (AlSi) can be used. The thickness of the lower portion 61 is, for example, 400 to 1000 nm. It should be noted that the lower portion 61 may be formed of an insulating material.

The first top layer 63 is formed of, for example, a metal material. The second top layer 64 is formed of, for example, a transparent conductive oxide. For the metal material forming the first top layer 63, for example, titanium, titanium nitride, molybdenum, tungsten, a molybdenum-tungsten alloy or a molybdenum-niobium alloy may be used. For the conductive oxide forming the second top layer 64, for example, ITO, IZO or IGZO may be used. The thickness of the first top layer 63 is, for example, 50 to 300 nm. The thickness of the second top layer 64 is, for example, 20 to 100 nm.

It should be noted that each of the bottom portion 60 and the lower portion 61 may include a plurality of layers formed of different materials. Further, the upper portion 62 may consist of a single layer. Each of the lower portion 61 and the upper portion 62 may include a layer formed of an insulating material.

In the embodiment, a transparent conductive oxide layer CL is provided between the rib 5 and the bottom portion 60. The conductive oxide layer CL can be formed of, for example, amorphous ITO, IZO or IGZO.

The conductive oxides (ITO, IZO or IGZO) which form the coating layers V1 and V2 of each of the lower electrodes LE1, LE2 and LE3 are burned in the manufacturing process described later. Therefore, the coating layers V1 and V2 have higher crystallinity than the conductive oxide layer CL.

FIG. 6 is a schematic cross-sectional view in which the bottom portion 60 and the vicinity of an end portion of the conductive oxide layer CL are enlarged. In the example of FIG. 6, the end portion E1 of the bottom portion 60 protrudes relative to the end portion E2 of the conductive oxide layer CL. By this configuration, a gap is formed under the end portion E1. The protrusion length of the end portion E1 from the end portion E2 is, for example, 50 to 1000 nm. In the example of FIG. 6, the end portion of the conductive oxide layer CL does not overlap the lower portion 61 in the Z-direction.

In the example of FIG. 6, part of the organic layer OR1 is located on the bottom portion 60 as well. The organic layer OR1 is spaced apart from the lower portion 61. The hole injection layer HIL of the organic layer OR1 is divided in the end portion E1. To the contrary, the hole transport layer HTL is not divided in the end portion E1. Similarly, the layers formed above the hole transport layer HTL in the organic layer OR1 (for example, the electron blocking layer EBL, the light emitting layer EML, the hole blocking layer HBL, the electron transport layer ETL and the electron injection layer EIL) are not divided in the end portion E1. The upper electrode UE1 continuously covers the organic layer OR1 and is in contact with the bottom portion 60 and the lower portion 61.

When the hole injection layer HIL is electrically connected to the partition 6, leak current through the hole injection layer HIL may be generated. Thus, the display quality may be degraded. Therefore, it is preferable that the hole injection layer HIL should be formed in an area which does not overlap the bottom portion 60, or should be divided in the end portion E1 as shown in the example of FIG. 6. For example, when thickness T1 of the conductive oxide layer CL is greater than thickness T2 of the hole injection layer HIL (T2<T1), the hole injection layer HIL is easily divided in the end portion E1.

If thickness T1 is too great, the other layers of the organic layer OR1 and the upper electrode UE1 could be also divided. If the upper electrode UE1 is divided, the voltage application from the partition 6 to the upper electrode UE1 may be adversely affected, and thus, there is a possibility that the organic layer OR1 does not emit light. For this reason, thickness T1 should be preferably less than the total thickness T3 of the hole injection layer HIL and the hole transport layer HTL (T1<T3). By this configuration, the hole transport layer HTL is not easily divided in the end portion E1. As a result, division of the layers located above the hole transport layer HTL in the organic layer OR1 and the upper electrode UE1 can be prevented.

For example, thickness T1 is 15 to 50 nm. In FIG. 6, the conductive oxide layer CL is thinner than the bottom portion 60. However, the configuration is not limited to this example.

The area located under the end portion E1 is filled with, for example, the hole transport layer HTL. It should be noted that a void may be formed in at least part of this area. In the example of FIG. 6, the end portion E2 of the conductive oxide layer CL overlaps the hole injection layer HIL located on the bottom portion 60 in the Z-direction. Further, the end portion E2 overlaps the upper electrode UE1 in the Z-direction.

Although this specification particularly looks at the configuration of the vicinity of the end portion of the stacked film FL1 in FIG. 6, the vicinities of the end portions of the stacked films FL2 and FL3 also have similar structures. For example, the thicknesses of the hole injection layer HIL and the hole transport layer HTL of each of the organic layers OR2 and OR3 are equal to those of the hole injection layer HIL and the hole transport layer HTL of the organic layer OR1. Thus, the hole injection layer HIL of each of the organic layers OR2 and OR3 is also divided in the end portion E1.

Now, this specification explains an example of the manufacturing method of the display device DSP according to the embodiment.

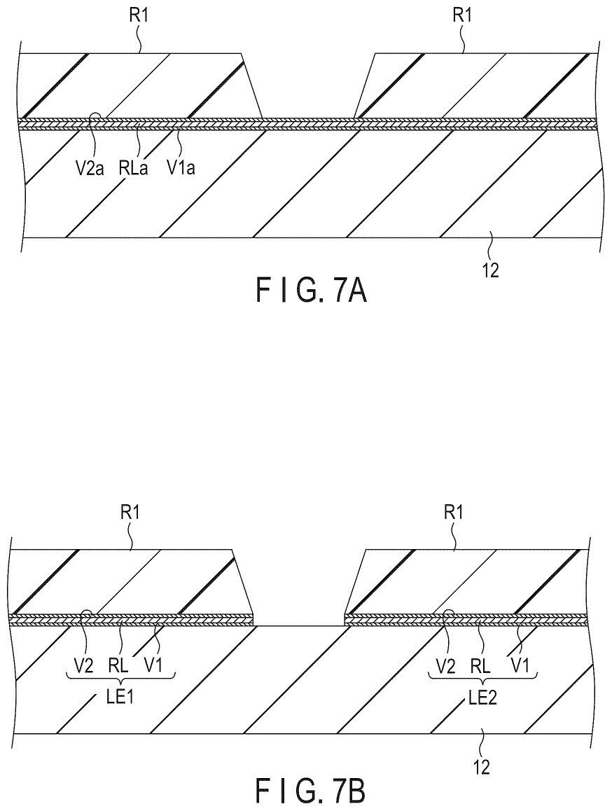

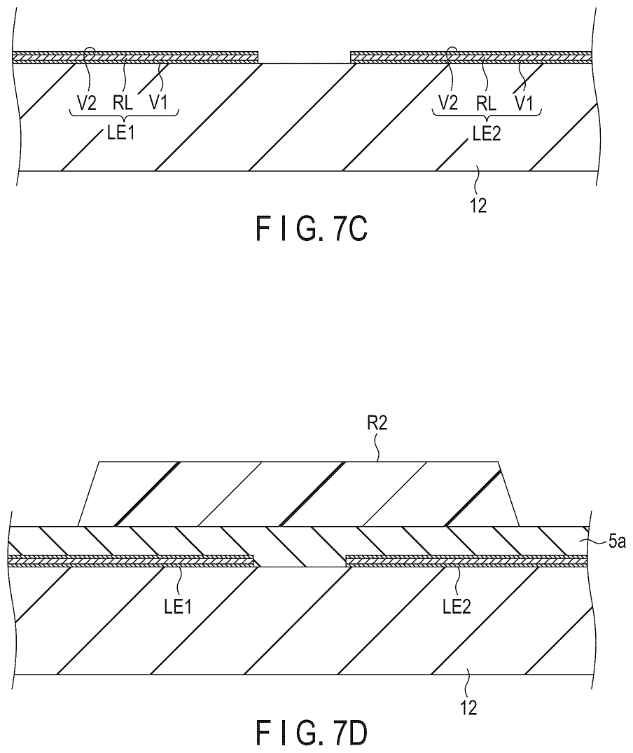

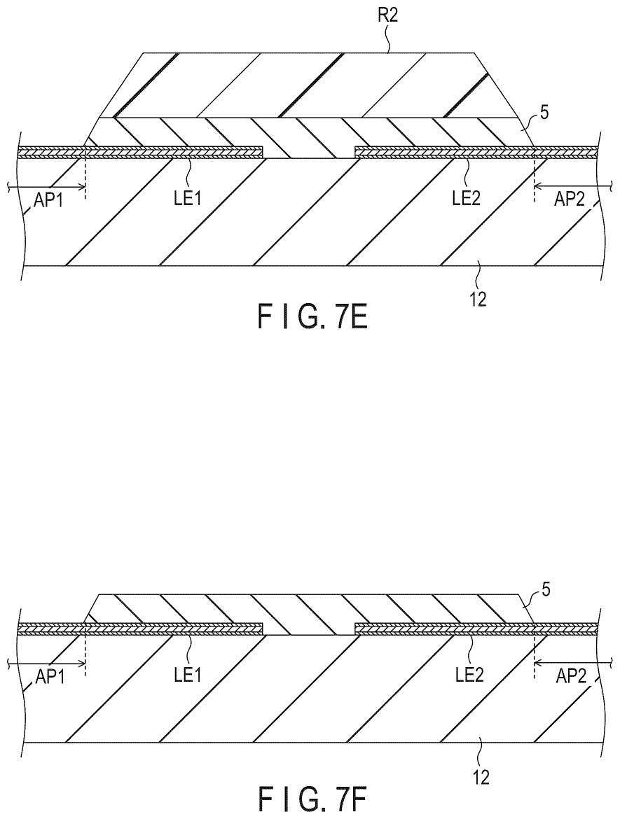

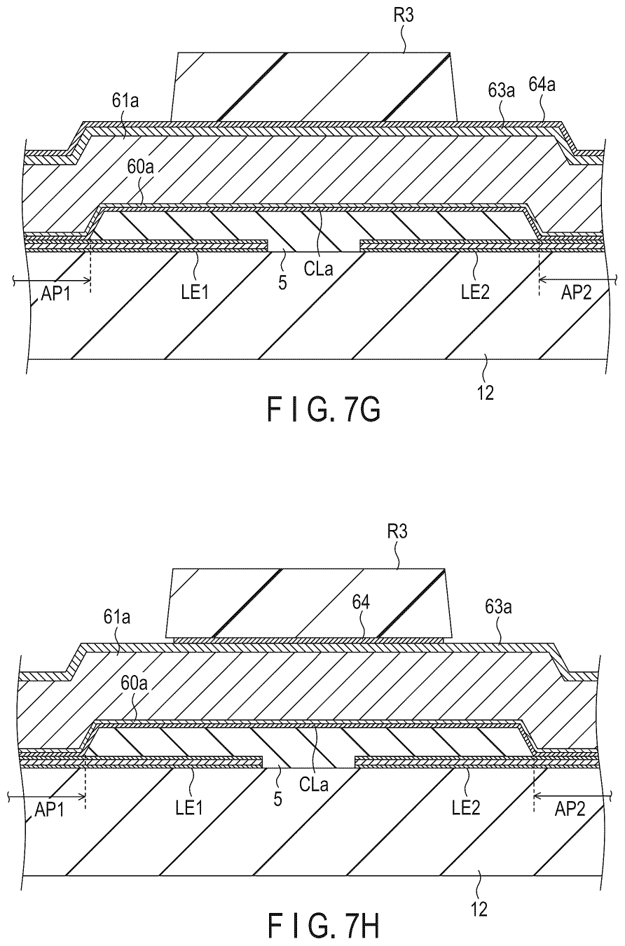

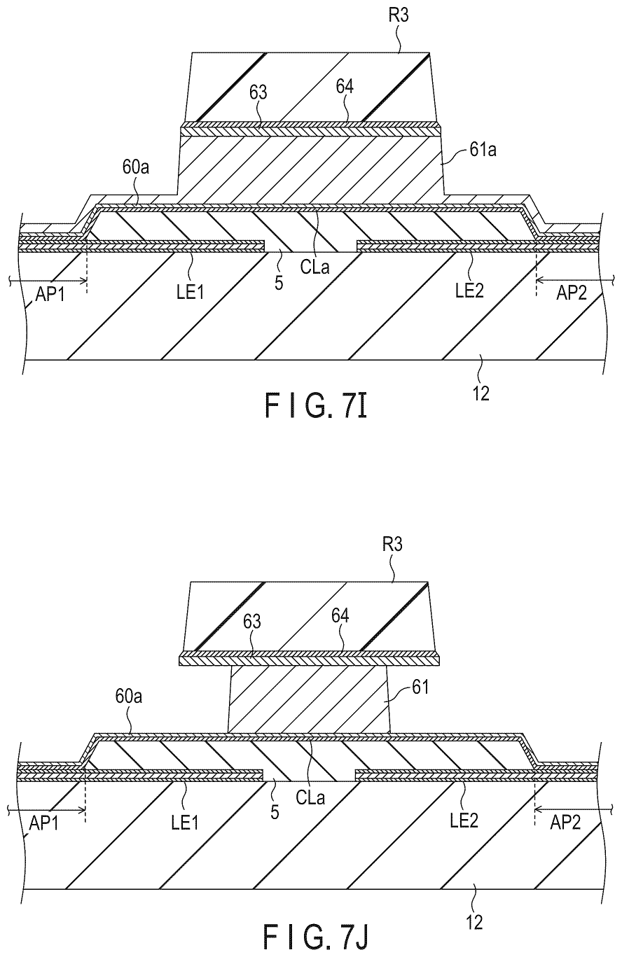

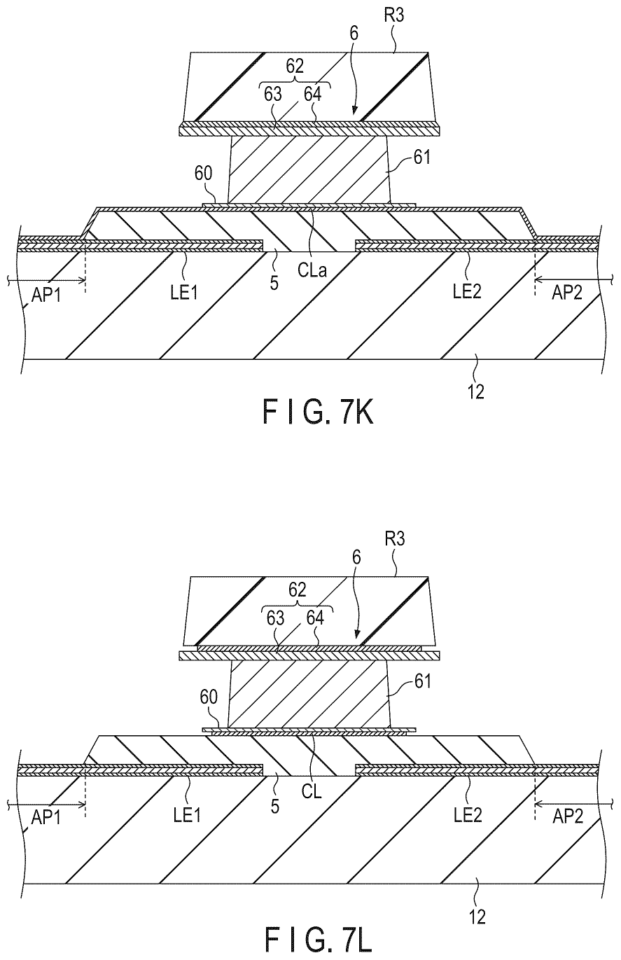

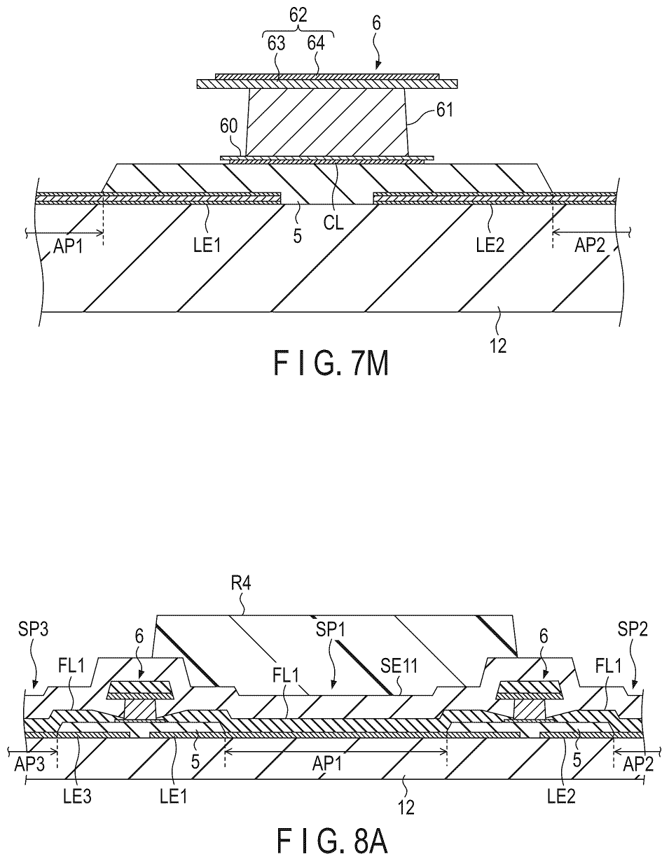

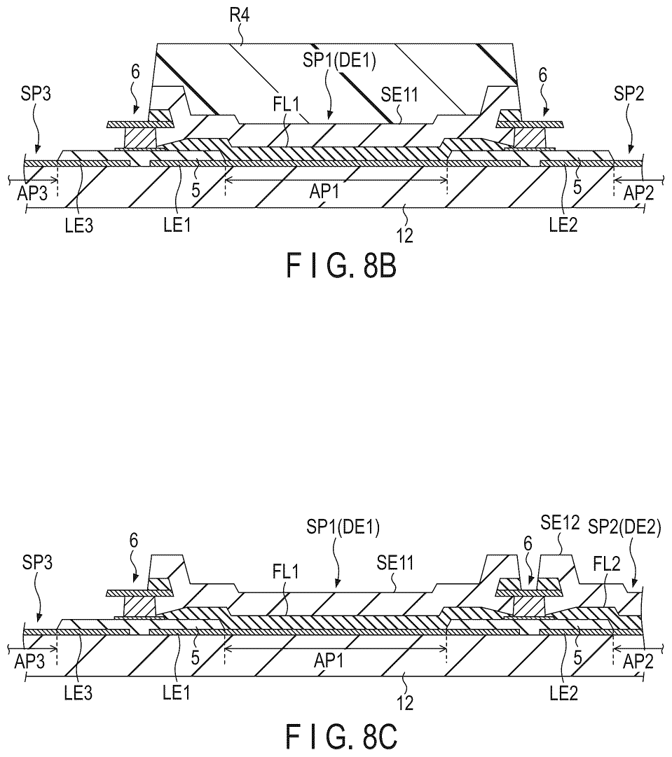

FIG. 7A to FIG. 7M are schematic cross-sectional views showing the manufacturing process before the formation of the display elements DE1, DE2 and DE3. FIG. 8A to FIG. 8D are schematic cross-sectional views showing the process of forming the display elements DE1, DE2 and DE3. In these figures, the illustrations of the substrate 10 and the circuit layer 11 are omitted.

To manufacture the display device DSP, first, the circuit layer 11 and the organic insulating layer 12 are formed on the substrate 10. Subsequently, as shown in FIG. 7A, a first coating layer V1a formed of a transparent conductive oxide, a reflective layer RLa formed of a metal material and a second coating layer V2a formed of a transparent conductive oxide are formed in order on the organic insulating layer 12. Further, a resist R1 having a shape corresponding to the lower electrodes LE1, LE2 and LE3 is provided on the second coating layer V2a.

The reflective layer RLa, the first coating layer V1a and the second coating layer V2a are layers to be processed into the reflective layer RL, first coating layer V1 and second coating layer V2 described above. All of these layers are formed in the entire part of the display area DA and the surrounding area SA by, for example, sputtering.

Subsequently, the reflective layer RLa and the coating layers V1a and V2a are patterned into the shape of the resist R1. Specifically, the portions of the reflective layer RLa and the coating layers V1a and V2a exposed from the resist R1 are removed by wet etching. Thus, as shown in FIG. 7B, the lower electrodes LE1, LE2 and LE3 which include the reflective layer RL, the first coating layer V1 covering the lower surface of the reflective layer RL and the second coating layer V2 covering the upper surface of the reflective layer RL are formed.

After the formation of the lower electrodes LE1, LE2 and LE3, the resist R1 is removed as shown in FIG. 7C. Further, the whole substrate is heated, thereby burning the conductive oxides constituting the coating layers V1 and V2.

Subsequently, as shown in FIG. 7D, a rib layer 5a which covers the lower electrodes LE1, LE2 and LE3 is formed by chemical vapor deposition (CVD). Further, a resist R2 having a shape corresponding to the rib 5 is provided on the rib layer 5a. The rib layer 5a is an inorganic insulating layer to be processed into the rib 5 and is formed in the entire part of the display area DA and the surrounding area SA.

Subsequently, the portion of the rib layer 5a exposed from the resist R2 is removed by dry etching. By this process, as shown in FIG. 7E, the rib 5 having the pixel apertures AP1, AP2 and AP3 overlapping the lower electrodes LE1, LE2 and LE3 is formed. After the formation of the rib 5, the resist R2 is removed as shown in FIG. 7F.

In the dry etching of the rib layer 5a, the resist R2 is also partly corroded, and its width is gradually reduced. In this manner, each end portion of the rib 5 along the pixel apertures AP1, AP2 and AP3 is tapered.

After the formation of the rib 5, as shown in FIG. 7G, a conductive oxide layer CLa, a bottom layer 60a, a lower layer 61a, a first top layer 63a and a second top layer 64a are formed in order by sputtering. Further, a resist R3 having a shape corresponding to the partition 6 is provided on the second top layer 64a. The conductive oxide layer CLa, the bottom layer 60a, the lower layer 61a, the first top layer 63a and the second top layer 64a are layers to be processed into the conductive oxide layer CL, bottom portion 60, lower portion 61 and upper portion 62 (first top layer 63 and second top layer 64) described above, and are formed in the entire part of the display area DA and the surrounding area SA. The conductive oxide layer CLa covers the lower electrodes LE1, LE2 and LE3 and the rib 5.

The conductive oxide layer CLa is formed of an amorphous conductive oxide. To form such an amorphous conductive oxide layer CLa, it is preferable that the partial pressure of water vapor in the chamber should be sufficiently increased in the sputtering of the conductive oxide layer CLa. For example, the partial pressure of water vapor in sputtering at the time of forming the conductive oxide layer CLa is higher than that of water vapor in sputtering at the time of forming the coating layers V1 and V2 of the lower electrodes LE1, LE2 and LE3.

Subsequently, the portion of the second top layer 64a exposed from the resist R3 is removed by wet etching. By this process, the second top layer 64 is formed as shown in FIG. 7H. In the example of FIG. 7H, the width of the second top layer 64 is slightly reduced compared to the resist R3.

Further, dry etching is applied using the resist R3 as a mask. Thus, the portion of the first top layer 63a exposed from the resist R3 is removed. By this process, the first top layer 63 is formed as shown in FIG. 7I.

It should be noted that, in this dry etching, the thickness of the portion of the lower layer 61a exposed from the resist R3 is also reduced. In addition, part of the resist R3 is corroded by the dry etching, and its width is reduced.

Subsequently, wet etching is applied to the lower layer 61a. By this process, the portion of the lower layer 61a exposed from the resist R3 is removed. Further, the side surfaces of the lower layer 61a are corroded, and its width is reduced compared to the top layers 63 and 64. By this process, the lower portion 61 is formed as shown in FIG. 7J.

After the formation of the lower portion 61, the bottom layer 60a is patterned by dry etching. Specifically, the portion of the bottom layer 60a exposed from the resist R3 is removed by the dry etching. By this process, the bottom portion 60 is formed as shown in FIG. 7K. In this dry etching, the width of the bottom portion 60 is reduced to a range in which the width is less than or equal to the widths of the top layers 63 and 64 and greater than or equal to the width of the lower portion 61.

By the above process, the partition 6 including the bottom portion 60, the lower portion 61 and the upper portion 62 (the first top layer 63 and the second top layer 64) is completed. After the formation of the partition 6, the conductive oxide layer CLa is patterned by wet etching. Specifically, the portion of the conductive oxide layer CLa exposed from the bottom portion 60 is removed by the wet etching. By this process, the conductive oxide layer CL is formed as shown in FIG. 7L. In this wet etching, as shown in FIG. 6, the end portion E2 of the conductive oxide layer CL is retracted relative to the end portion E1 of the bottom portion 60.

The conductive oxide layer CLa is amorphous as it is not burned before this wet etching. For the etchant of this conductive oxide layer CLa, for example, oxalic acid can be used. The second coating layer V2 of each of the lower electrodes LE1, LE2 and LE3 is already burned at the time of the wet etching, and has higher crystallinity than the conductive oxide layer CLa. Therefore, the etching speed of the second coating layer V2 by oxalic acid is sufficiently slower than the conductive oxide layer CLa. Thus, the second coating layer V2 is not easily corroded. In addition, in wet etching using oxalic acid, the rib 5 formed of silicon nitride, silicon oxide or silicon oxynitride is not easily corroded.

In the wet etching of the conductive oxide layer CLa, the second top layer 64 formed of conductive oxide could be also corroded. In this manner, as shown in FIG. 7L, the width of the second top layer 64 is reduced relative to the width of the first top layer 63. After the formation of the conductive oxide layer CL, the resist R3 is removed as shown in FIG. 7M.

Subsequently, a process for forming the display elements DE1, DE2 and DE3 is performed. In the present embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

To form the display element DE1, first, as shown in FIG. 8A, the stacked film FL1 and the sealing layer SE11 are formed. The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1.

The organic layer OR1, the upper electrode UE1 and the cap layer CP1 are formed by vapor deposition. The sealing layer SE11 is formed by CVD. The stacked film FL1 is divided into a plurality of portions by the partition 6 having an overhang shape. The sealing layer SE11 continuously covers the portions into which the stacked film FL1 is divided, and the partition 6.

After the formation of the stacked film FL1 and the sealing layer SE11, as shown in FIG. 8A, a resist R4 is provided on the sealing layer SE11. The resist R4 covers subpixel SP1 and part of the partition 6 around the subpixel.

Subsequently, as shown in FIG. 8B, the portions of the stacked film FL1 and the sealing layer SE11 exposed from the resist R4 are removed by etching using the resist R4 as a mask. By this process, the display element DE1 is formed in subpixel SP1. For example, this etching includes wet etching and dry etching processes which are performed in order for the sealing layer SE11, the cap layer CP1, the upper electrode UE1 and the organic layer OR1. After these etching processes, the resist R4 is removed.

The display element DE2 is formed by a procedure similar to that of the display element DE1. Specifically, when the display element DE2 is formed, the stacked film FL2 and the sealing layer SE12 are formed in the entire display area DA. The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 are formed by vapor deposition. The sealing layer SE12 is formed by CVD. The stacked film FL2 is divided into a plurality of portions by the partition 6 having an overhang shape. The sealing layer SE12 continuously covers the portions into which the stacked film FL2 is divided, and the partition 6.

Subsequently, the stacked film FL2 and the sealing layer SE12 are patterned. By this process, the display element DE2 is formed in subpixel SP2 as shown in FIG. 8C.

The display element DE3 is formed by a procedure similar to the procedures of the display elements DE1 and DE2. Specifically, when the display element DE3 is formed, the stacked film FL3 and the sealing layer SE13 are formed in the entire display area DA. The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 are formed by vapor deposition. The sealing layer SE13 is formed by CVD. The stacked film FL3 is divided into a plurality of portions by the partition 6 having an overhang shape. The sealing layer SE13 continuously covers the portions into which the stacked film FL3 is divided, and the partition 6.

Subsequently, the stacked film FL3 and the sealing layer SE13 are patterned. By this process, the display element DE3 is formed in subpixel SP3 as shown in FIG. 8D.

After the display elements DE1, DE2 and DE3 are formed, the resin layer RS1, sealing layer SE2 and resin layer RS2 shown in FIG. 3 are formed in order. The display device DSP is completed through this process.

In the embodiment explained above, the partition 6 having an overhang shape allows the acquisition of the display device DSP comprising the display elements DE1, DE2 and DE3 which are separated from each other for the respective subpixels SP1, SP2 and SP3 and are individually sealed.

Further, as the conductive oxide layer CL is provided under the partition 6, the yield of the display device DSP can be improved. If the conductive oxide layer CL is not provided, the lower electrodes LE1, LE2 and LE3 and the rib 5 may be damaged in etching for forming the partition 6. To the contrary, when the conductive oxide layer CL is provided, the conductive oxide layer CL functions as the etching stopper of etching for forming the partition 6. Thus, the damage to the lower electrodes LE1, LE2 and LE3 and the rib 5 is prevented.

It should be noted that, even in a case where the conductive oxide layer CL is not provided, the damage to the rib 5 could be prevented by forming the rib 5 using a material in which the etching speed of dry etching is slow, such as silicon oxide or silicon oxynitride. However, silicon oxide and silicon oxynitride are inferior to silicon nitride in the coverability. Therefore, for example, there is a possibility that a problem such as the generation of a moisture path in the rib 5 occurs near the end portions of the lower electrodes LE1, LE2 and LE3. To the contrary, when the conductive oxide layer CL is provided, for example, the damage to the rib 5 can be prevented while using silicon nitride which is excellent in coverability although the etching speed of dry etching is fast.

The second coating layer V2 of each of the lower electrodes LE1, LE2 and LE3 protects the reflective layer RL from etching for forming the partition 6. This effect is further improved as the thickness of the second coating layer V2 is increased. However, when the second coating layer V2 is made thick, the luminance of the display elements DE1, DE2 and DE3 and the light emission efficiency could be decreased. To the contrary, as in the case of the embodiment, when the conductive oxide layer CL is provided above the second coating layer V2, the second coating layer V2 can be formed so as to be thin compared to a case where the conductive oxide layer CL is not provided. By this configuration, the improvement of the luminance of the display elements DE1, DE2 and DE3 and the light emission efficiency can be expected.

As a method for protecting the lower electrodes LE1, LE2 and LE3 from etching for forming the partition 6, unlike the embodiment, the pixel apertures AP1, AP2 and AP3 could be formed after the formation of the partition 6 instead of forming the partition 6 after forming the pixel apertures AP1, AP2 and AP3. However, in this case, a photolithographic process for processing the rib 5 is added compared to the embodiment.

Specifically, the partition 6 is connected to the feed lines of common voltage through the apertures of the rib 5 provided in the surrounding area SA. To provide these apertures, a photolithographic process for the rib 5 needs to be performed before the formation of the partition 6. Therefore, in a case where the pixel apertures AP1, AP2 and AP3 are formed after the formation of the partition 6, a photolithographic process needs to be performed for the rib 5 at least twice.

To the contrary, in a case where the pixel apertures AP1, AP2 and AP3 are provided before the formation of the partition 6 like the embodiment, the apertures of the surrounding area SA can be also provided in the photolithographic process of the pixel apertures AP1, AP2 and AP3 at the same time. Thus, compared to a case where the pixel apertures AP1, AP2 and AP3 are formed after the formation of the partition 6, the number of times of performing a photolithographic process can be reduced.

Further, in a case where the pixel apertures AP1, AP2 and AP3 are formed after the formation of the partition 6, there is a possibility that a resist for the processing of the rib 5 cannot be uniformly applied by the partition 6 having an overhang shape. To the contrary, in a case where the pixel apertures AP1, AP2 and AP3 are provided before the formation of the partition 6 like the embodiment, a resist for the processing of the rib 5 (the resist R2 in FIG. 7D) can be uniformly applied. Thus, the accuracy of the shape of the rib 5 is improved.

Various desirable effects can be obtained from the embodiment in addition to the above description.

### Second Embodiment

A second embodiment is explained. The same structures as the first embodiment are denoted by the same reference numbers. Thus, descriptions thereof are omitted. Regarding a display device DSP, to configurations or manufacturing processes which are not particularly referred to in this embodiment, configurations or manufacturing processes similar to those of the first embodiment can be applied.

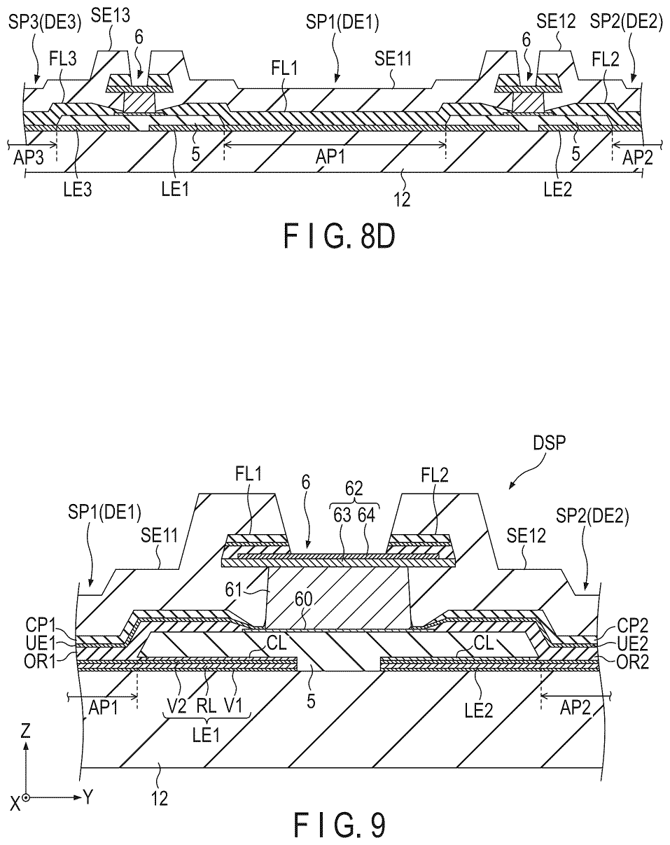

FIG. 9 is a schematic cross-sectional view of a display device DSP according to the second embodiment and shows the configuration of a partition 6 and its vicinity in a manner similar to that of FIG. 5. In the example of FIG. 9, the positions of conductive oxide layers CL are different from the example of FIG. 5.

In this embodiment, the conductive oxide layers CL are provided between lower electrodes LE1 and LE2 and a rib 5. Although not shown in FIG. 9, the conductive oxide layer CL is also provided between a lower electrode LE3 and the rib 5. The conductive oxide layers CL cover the peripheral portions of the second coating layers V2 of the lower electrodes LE1, LE2 and LE3. In this embodiment, the bottom portion 60 of the partition 6 is in contact with the upper surface of the rib 5.

In the example of FIG. 9, the end portions of the lower electrodes LE1 and LE2 overlap a lower portion 61 in a Z-direction. Organic layers OR1 and OR2 are spaced apart from the lower portion 61. An end portion of each conductive oxide layer CL overlaps the lower portion 61 in the Z-direction. However, the other end portion does not overlap the lower portion 61 in the Z-direction.

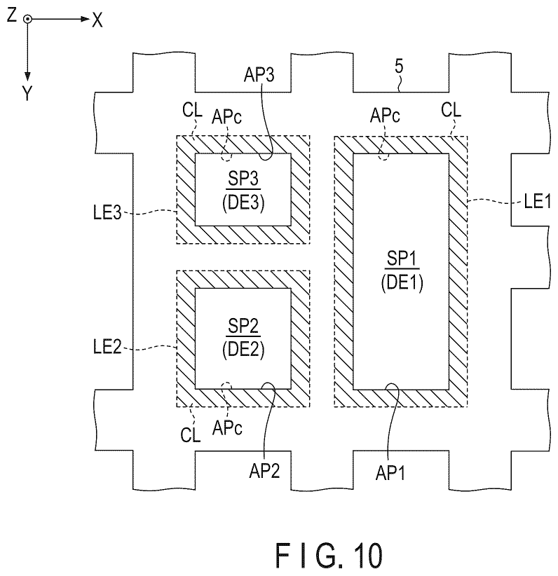

FIG. 10 is a schematic plan view of the rib 5, the lower electrodes LE1, LE2 and LE3 and the conductive oxide layers CL according to the embodiment. In the figure, the portions shown by diagonal lines correspond to the conductive oxide layers CL.

The conductive oxide layers CL are provided in areas where the lower electrodes LE1, LE2 and LE3 overlap the rib 5. In other words, the conductive oxide layers CL have respective apertures APC overlapping respective pixel apertures AP1, AP2 and AP3. From another viewpoint, the conductive oxide layers CL surround respective display elements DE1, DE2 and DE3.

In FIG. 10, the respective lower electrodes LE1, LE2 and LE3 and three conductive oxide layers CL overlapping these lower electrodes LE1, LE3 and LE3, respectively, are shown. These conductive oxide layers CL are provided for all of the lower electrodes LE1, LE2 and LE3 of the display device DSP.

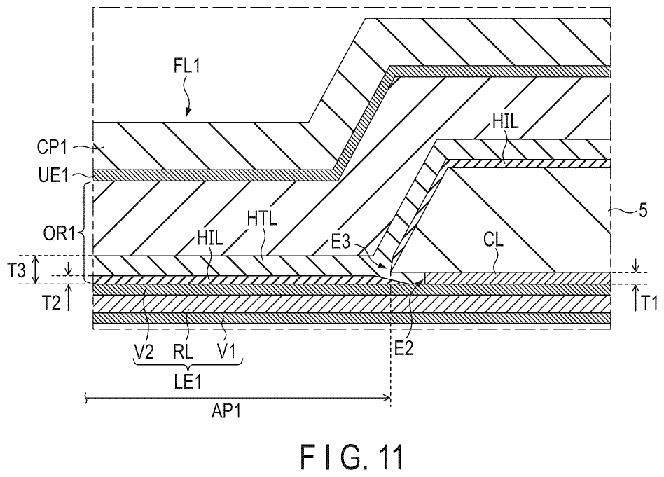

FIG. 11 is a schematic cross-sectional view in which the partition 6 shown in FIG. 9 and its vicinity are enlarged. In this figure, a substrate 10, a circuit layer 11, an organic insulating layer 12, a sealing layer SE11, resin layers RS1 and RS2 and a sealing layer SE2 are omitted.

The conductive oxide layer CL is in contact with the upper surface of the second coating layer V2. In the example of FIG. 11, the end portion E3 of the rib 5 along the pixel aperture AP1 protrudes relative to the end portion E2 of the conductive oxide layer CL. By this configuration, a gap is formed under the end portion E3. The protrusion length of the end portion E3 from the end portion E2 is, for example, 50 to 1000 nm.

In the example of FIG. 11, the hole injection layer HIL of the organic layer OR1 is divided in the end portion E3. This configuration can prevent leak current through the hole injection layer HIL in a manner similar to that of the first embodiment.

To the contrary, a hole transport layer HTL is not divided in the end portion E3. Similarly, the layers formed above the hole transport layer HTL in the organic layer OR1 (for example, an electron blocking layer EBL, a light emitting layer EML, a hole blocking layer HBL, an electron transport layer ETL and an electron injection layer EIL) are not divided in the end portion E3.

In a manner similar to that of the first embodiment, for example, thickness T1 of the conductive oxide layer CL should be preferably greater than thickness T2 of the hole injection layer HIL (T2<T1) and less than the total thickness T3 of the hole injection layer HIL and the hole transport layer HTL (T1<T3). By this configuration, the hole injection layer HIL is easily divided in the end portion E3, and the hole transport layer HTL is not easily divided in the end portion E3.

In the example of FIG. 11, the area under the end portion E3 is filled with the hole transport layer HTL. It should be noted that a void may be formed in at least part of this area. Although this specification particularly looks at the configuration of the vicinity of a stacked film FL1 in FIG. 11, the vicinities of the end portions of stacked films FL2 and FL3 also have similar configurations.

In this embodiment, the conductive oxide layer CL is formed of, for example, amorphous IZO or IGZO. The rib 5 is formed of, for example, silicon oxynitride.

Now, this specification explains an example of the manufacturing method of the display device DSP according to the embodiment.

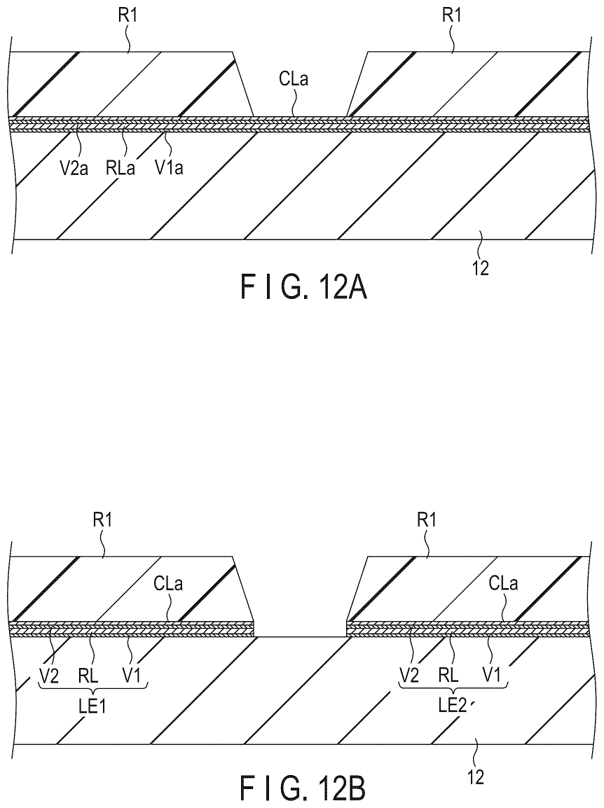

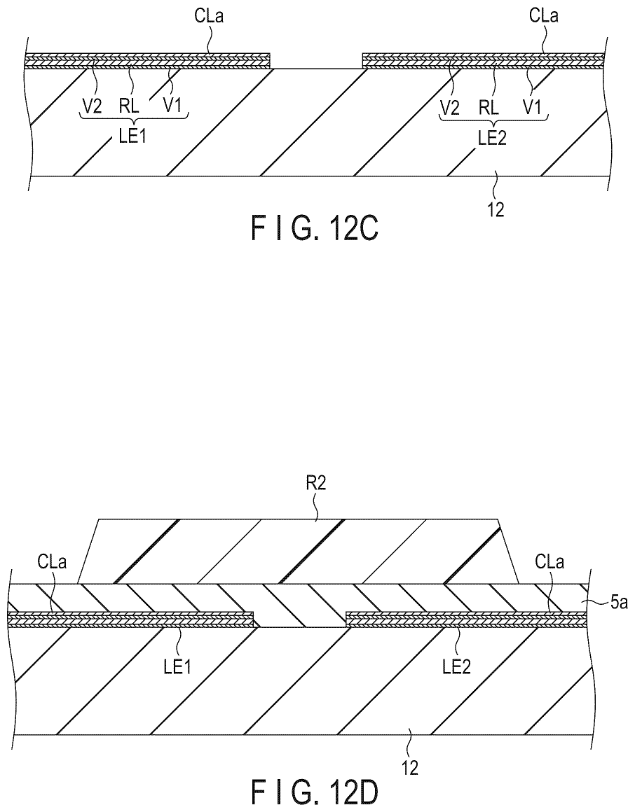

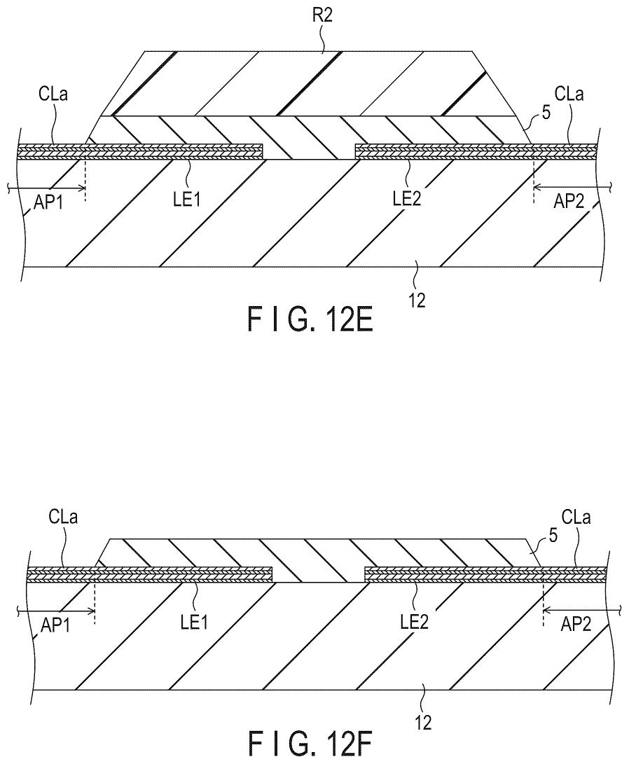

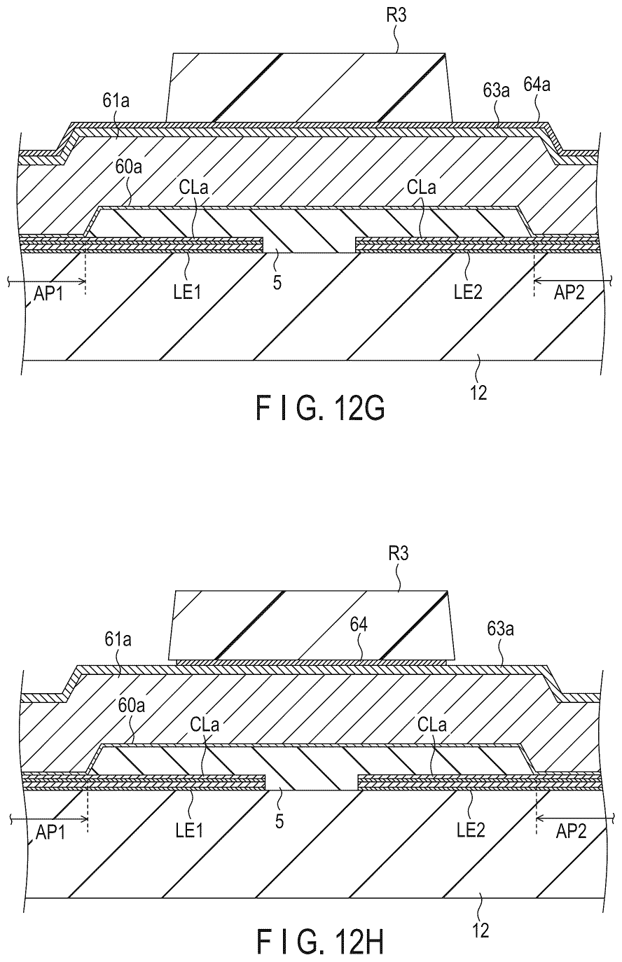

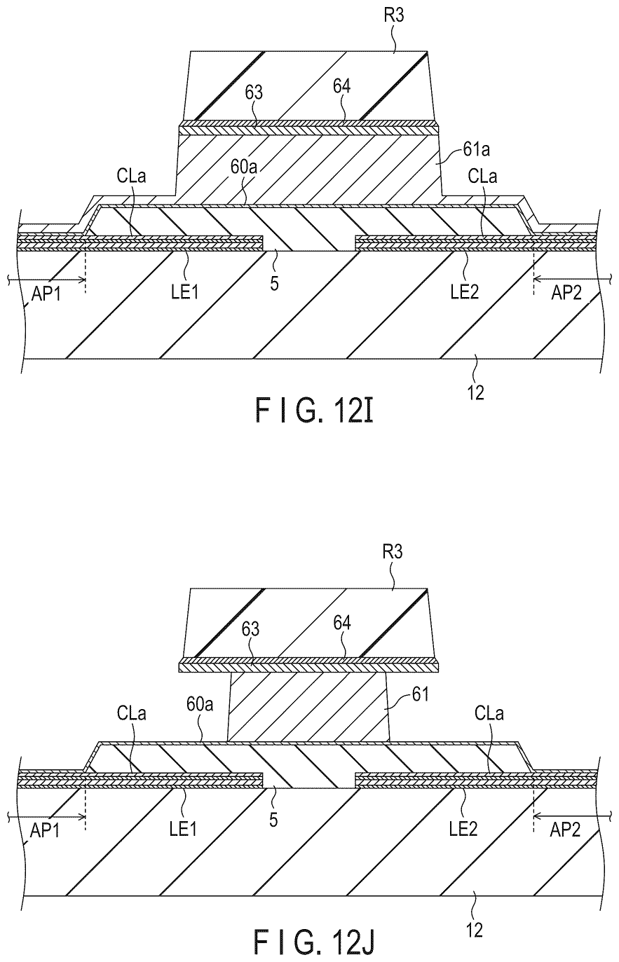

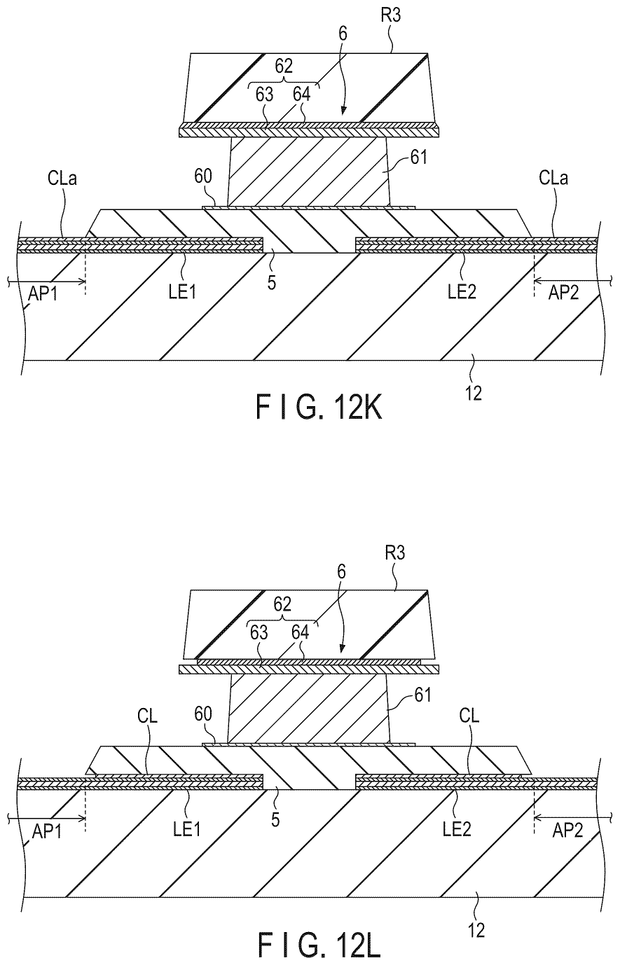

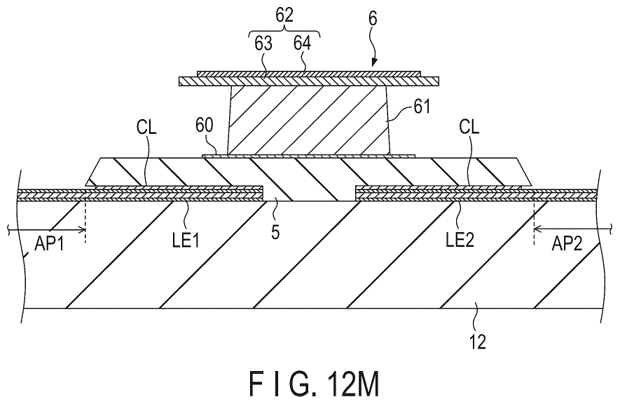

FIG. 12A to FIG. 12M are schematic cross-sectional views showing the manufacturing process before the formation of the display elements DE1, DE2 and DE3. In these figures, the illustrations of the substrate 10 and the circuit layer 11 are omitted. The process of forming the display elements DE1, DE2 and DE3 is similar to that of FIG. 8A to FIG. 8D.

To manufacture the display device DSP, first, the circuit layer 11 and the organic insulating layer 12 are formed on the substrate 10. Subsequently, in a manner similar to that of the first embodiment, a first coating layer V1a, a reflective layer RLa and a second coating layer V2a are formed in order on the organic insulating layer 12.

In this embodiment, as shown in FIG. 12A, a conductive oxide layer CLa is formed on the second coating layer V2a by sputtering. Further, a resist R1 having a shape corresponding to the lower electrodes LE1, LE2 and LE3 is provided on the conductive oxide layer CLa.

Subsequently, the conductive oxide layer CLa, the reflective layer RLa and the coating layers V1a and V2a are patterned into the shape of the resist R1. Specifically, the portions of the conductive oxide layer CLa, the reflective layer RLa and the coating layers V1a and V2a exposed from the resist R1 are removed by wet etching. Thus, as shown in FIG. 12B, the lower electrodes LE1, LE2 and LE3 each of which includes a reflective layer RL, a first coating layer V1 and the second coating layer V2 are formed. At this time, the entire lower electrodes LE1, LE2 and LE3 are covered with the conductive oxide layer CLa.

After the formation of the lower electrodes LE1, LE2 and LE3, the resist R1 is removed as shown in FIG. 12C. Further, the whole substrate is heated, thereby burning the conductive oxides constituting the coating layers V1 and V2.

In this embodiment, the coating layers V1 and V2 are formed of ITO. The conductive oxide layer CLa is formed of IZO or IGZO. Thus, the coating layers V1 and V2 are formed of a conductive oxide different from that of the conductive oxide layer CL.

The temperature of the above burning is set so as to be a temperature at which ITO is crystallized, and IZO or IGZO is not crystallized. In other words, the coating layers V1 and V2 are crystallized by the above burning while the conductive oxide layer CLa maintains amorphousness.

Subsequently, as shown in FIG. 12D, a rib layer 5a which covers the lower electrodes LE1, LE2 and LE3 is formed by CVD. Further, a resist R2 having a shape corresponding to the rib 5 is provided on the rib layer 5a. In this embodiment, the rib layer 5a is formed of silicon oxynitride.

Subsequently, the portion of the rib layer 5a exposed from the resist R2 is removed by dry etching. By this process, as shown in FIG. 12E, the rib 5 having the pixel apertures AP1, AP2 and AP3 overlapping the lower electrodes LE1, LE2 and LE3 is formed. After the formation of the rib 5, the resist R2 is removed as shown in FIG. 12F.

After the formation of the rib 5, as shown in FIG. 12G, a bottom layer 60a, a lower layer 61a, a first top layer 63a and a second top layer 64a are formed in order by sputtering. Further, a resist R3 having a shape corresponding to the partition 6 is provided on the second top layer 64a.

Subsequently, the portion of the second top layer 64a exposed from the resist R3 is removed by wet etching. By this process, a second top layer 64 is formed as shown in FIG. 12H. In the example of FIG. 12H, the width of the second top layer 64 is slightly reduced compared to the resist R3.

Further, dry etching is applied using the resist R3 as a mask. Thus, the portion of the first top layer 63a exposed from the resist R3 is removed. By this process, a first top layer 63 is formed as shown in FIG. 12I. In a manner similar to that of the first embodiment, in this dry etching, the thickness of the portion of the first layer 61a exposed from the resist R3 is also reduced.

Subsequently, wet etching is applied to the first layer 61a. By this process, the portion of the lower layer 61a exposed from the resist R3 is removed. Further, the side surfaces of the lower layer 61a is corroded, and its width is reduced compared to the top layers 63 and 64. By this process, the lower portion 61 is formed as shown in FIG. 12J.

After the formation of the lower portion 61, the bottom layer 60a is patterned by dry etching. Specifically, the portion of the bottom layer 60a exposed from the resist R3 is removed by the dry etching. By this process, the bottom portion 60 is formed as shown in FIG. 12K.

By the above process, the partition 6 including the bottom portion 60, the lower portion 61 and an upper portion 62 is completed. After the formation of the partition 6, the conductive oxide layer CLa is patterned by wet etching. Specifically, the portion of the conductive oxide layer CLa exposed from the rib 5 through the pixel apertures AP1, AP2 and AP3 is removed by the wet etching. By this process, as shown in FIG. 12L, the conductive oxide layers CL which cover the peripheral portions of the lower electrodes LE1, LE2 and LE3 are formed.

In a manner similar to that of the first embodiment, for the etchant of the conductive oxide layer CLa, for example, oxalic acid can be used. In this wet etching, as shown in FIG. 11, the end portion E2 of the conductive oxide layer CL is retracted relative to the end portion E3 of the rib 5 along the pixel apertures AP1, AP2 and AP3.

After the formation of the conductive oxide layers CL, the resist R3 is removed as shown in FIG. 12M. A process which is subsequently performed for forming the display elements DE1, DE2 and DE3 is similar to that of the first embodiment.

Even the configuration of this embodiment can protect the lower electrodes LE1, LE2 and LE3 from etching for forming the partition 6 in a manner similar to that of the first embodiment. In addition, compared to a case where the conductive oxide layer CL is not provided, the second coating layer V2 can be formed so as to be thin. By this configuration, the improvement of the luminance of the display elements DE1, DE2 and DE3 and the light emission efficiency can be expected. Moreover, as the pixel apertures AP1, AP2 and AP3 are provided before the formation of the partition 6, the number of photolithographic processes for the rib 5 can be reduced.

In this embodiment, the rib 5 is not covered with the conductive oxide layer CLa. Thus, the rib 5 is exposed to the etching of the partition 6. However, as the rib 5 is formed of silicon oxynitride as described above, the damage to the rib 5 can be prevented compared to a case where the rib 5 is formed of silicon nitride.

All of the display devices and manufacturing methods thereof that can be implemented by a person of ordinary skill in the art through arbitrary design changes to the display device and manufacturing method thereof disclosed above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a lower electrode;
a rib which has a pixel aperture overlapping the lower electrode and covers an end portion of the lower electrode;
a partition which includes a bottom portion provided on the rib, a lower portion provided on the bottom portion, and an upper portion provided on the lower portion and protruding from a side surface of the lower portion;
an organic layer which is in contact with the lower electrode through the pixel aperture and emits light based on application of voltage;
an upper electrode which covers the organic layer and is in contact with at least one of the bottom portion and the lower portion; and
a transparent conductive oxide layer provided between the rib and the bottom portion.

2. The display device of claim 1, wherein
the conductive oxide layer is formed of amorphous ITO, IZO or IGZO.

3. The display device of claim 1, wherein
the rib is formed of silicon nitride, silicon oxide or silicon oxynitride.

4. The display device of claim 1, wherein
an end portion of the bottom portion protrudes from an end portion of the conductive oxide layer.

5. The display device of claim 1, wherein
the organic layer includes a hole injection layer which is in contact with the lower electrode, and
a thickness of the conductive oxide layer is greater than a thickness of the hole injection layer.

6. The display device of claim 5, wherein
the organic layer further includes a hole transport layer which covers the hole injection layer, and
the thickness of the conductive oxide layer is less than a total thickness of the hole injection layer and the hole transport layer.

7. The display device of claim 1, wherein
the lower electrode includes:
a reflective layer formed of a metal material; and
a coating layer formed of a transparent conductive oxide whose crystallinity is higher than the conductive oxide layer, and covering an upper surface of the reflective layer.

8. The display device of claim 1, wherein
an end portion of the bottom portion protrudes from an end portion of the conductive oxide layer, and
the bottom portion and the lower portion are formed of different materials.

9. The display device of claim 1, wherein
the end portion of the lower electrode overlaps the lower portion.

10. The display device of claim 1, wherein
the upper portion includes a first top layer provided on the lower portion, and a second top layer provided on the first top layer,
the first top layer and the second top layer are formed of different materials, and
an end portion of the first top layer protrudes from an end portion of the second top layer.

11. The display device of claim 1, wherein
the organic layer is spaced apart from the lower portion.

12. The display device of claim 1, wherein
an end portion of the conductive oxide layer does not overlap the lower portion.

13. The display device of claim 1, wherein
the organic layer includes a hole injection layer which is contact with the lower electrode, and
an end portion of the conductive oxide layer overlaps the hole injection layer.

14. The display device of claim 1, wherein
an end portion of the conductive oxide layer overlaps the upper electrode.

15. A display device comprising:
a lower electrode;
a rib which has a pixel aperture overlapping the lower electrode and covers an end portion of the lower electrode;
a partition which includes a bottom portion provided on the rib, a lower portion provided on the bottom portion, and an upper portion provided on the lower portion and protruding from a side surface of the lower portion;
an organic layer which is in contact with the lower electrode through the pixel aperture and emits light based on application of voltage;
an upper electrode which covers the organic layer and is in contact with at least one of the bottom portion and the lower portion; and
a transparent conductive oxide layer which is provided between the lower electrode and the rib and has an aperture overlapping the pixel aperture.

16. The display device of claim 15, wherein
the lower electrode includes:
a reflective layer formed of a metal material; and
a coating layer which is formed of a transparent conductive oxide different from the conductive oxide layer and covers an upper surface of the reflective layer.

17. The display device of claim 15, wherein
the end portion of the lower electrode overlaps the lower portion.

18. The display device of claim 15, wherein
the upper portion includes a first top layer provided on the lower portion, and a second top layer provided on the first top layer,
the first top layer and the second top layer are formed of different materials, and
an end portion of the first top layer protrudes from an end portion of the second top layer.

19. The display device of claim 15, wherein
the organic layer is spaced apart from the lower portion.

20. The display device of claim 15, wherein
an end portion of the conductive oxide layer overlaps the lower portion, and
the other end portion of the conductive oxide layer does not overlap the lower portion.
